(19) United States
(12) Patent Application Publication
(10) Pub. No.: US 2022/0059594 A1
(43) Pub. Date: Feb. 24, 2022

(54) SOLID-STATE IMAGING DEVICE

(71) Applicants: TOWER PARTNERS SEMICONDUCTOR CO., LTD., Uozu City (JP); TOWER SEMICONDUCTOR LTD., Migdal Haemek (IL)

(72) Inventor: Katsuya FURUKAWA, Toyama (JP)

(73) Assignees: TOWER PARTNERS SEMICONDUCTOR CO., LTD., Uozu City (JP); TOWER SEMICONDUCTOR LTD., Migdal Haemek (IL)

(21) Appl. No.: 17/409,785

(22) Filed: Aug. 23, 2021

(30) Foreign Application Priority Data
Aug. 24, 2020 (JP) 2020-140645

(51) Int. Cl. H01L 27/146

(52) U.S. Cl. CPC H01L 27/14623; H01L 27/14603; H01L 27/14636; H01L 27/14643; H01L 27/1464

(57) ABSTRACT

A solid-state imaging device includes a first semiconductor substrate, photoelectric conversion portions arrayed on the first semiconductor substrate and configured to convert incident light to charges, a charge storage portion configured to hold charges transferred from a corresponding one of the photoelectric conversion portions via a transfer transistor, and an interconnect layer stacked on the first semiconductor substrate and including a plurality of metal interconnects. The incident light enters the first semiconductor substrate from a back surface side that is an opposite side to the interconnect layer. The solid-state imaging device further includes a light absorbing film between the photoelectric conversion portions and the metal interconnects.

### CROSS-REFERENCE TO RELATED APPLICATION

This application claims priority to Japanese Patent Application No. 2020-140645 filed on Aug. 24, 2020, the entire disclosure of which is incorporated by reference herein.

### BACKGROUND

As solid-state imaging devices used for various types of cameras, such as digital still cameras, smartphones, in-vehicle cameras, or the like, complementary metal oxide semiconductor (CMOS) image sensors have been more commonly used than charge coupled devices (CCD) image sensors. Reasons for this are as follows: CMOS image sensors are excellent in power consumption, read speed, or the like; sensitivity of CMOS image sensors has been remarkably increased by a back side illumination (BSI) structure; and the like.

In general CMOS image sensors, a rolling shutter system in which pixel signals are sequentially read from pixels for each row has been used. In this case, for example, in a case where a subject moving at high speed is imaged, an image is distorted in some cases. Therefore, CMOS image sensors employing a global shutter system in which all pixels are simultaneously read to a charge holding portion and signals are output have been developed.

However, to achieve the global shutter system, it is necessary to reduce an area of photodiodes and provide the charge holding portion (memory node portion), and this becomes a cause for reducing the number of saturation electrons and sensitivity characteristics, compared to a case where the rolling shutter system is employed.

In the global shutter system, read signals are temporarily held in the charge holding portion. When parasitic light enters the charge holding portion while read signals are held therein, noise is generated. In order to suppress a parasitic light sensitivity (PLS) that is a sensitivity to such parasitic light, the charge holding potion is shielded by a metal light shielding film.

In a front-side irradiation type image sensor, it is easy to dispose a light shielding film directly on the charge holding portion. However, in a back-side irradiation type image sensor, a back surface of a substrate is irradiated with light, and therefore, a similar light shielding method to that for the front-side irradiation type image sensor is not effective.

On the other hand, Japanese Patent No. 6052353 discloses that, in a back-side irradiation type image sensor, an element having a large depth from a back surface of a substrate is formed and a metal film is buried therein to form a light shielding film.

In Japanese Patent No. 4835710, a configuration in which a first substrate and a second substrate are connected to each other via Cu—Cu bonding in a back-side irradiation type image sensor is disclosed. In Japanese Patent No. 4835710, a photodiode (PD) and a gate and a drain of a transistor that reads charges from the PD are provided in the first substrate, and a memory node portion and a transistor that reads charges therefrom to a field diffusion (FD) or the like are disposed on the second substrate. Furthermore, the memory node portion of the second substrate is connected to the drain of the transistor of the first substrate and an interconnect capacitance (a structure in which a high dielectric material is interposed) used for ensuring a capacitance in the second substrate is disposed to thus increase a PD area.

### SUMMARY

In an image sensor of the global shutter system, a drain portion of a transfer transistor that reads charges is coupled to a memory node portion. As a result, the drain portion is also a cause for generating a PLS. Therefore, in order to improve PLS characteristics, it is desired that the drain portion is also shielded from light.

If the image sensor is a back-side irradiation type, light that has entered from the back surface of the substrate is reflected by an interconnect, leaks into the drain portion, and thus, causes a PLS in some cases. This is remarkable during irradiation of high incident light (when an incident angle of light is large).

It will be described hereinafter to improve PLS characteristics in a back-side irradiation type solid-state imaging device.

A solid-state imaging device according to the present disclosure includes a first semiconductor substrate, photoelectric conversion portions arrayed on the first semiconductor substrate and configured to convert incident light to charges, a charge storage portion configured to hold charges transferred from a corresponding one of the photoelectric conversion portions via a transfer transistor, and an interconnect layer stacked on the first semiconductor substrate and including a plurality of metal interconnects. The incident light enters the first semiconductor substrate from a back surface side that is an opposite side to the interconnect layer. The solid-state imaging device further includes a light absorbing film between the photoelectric conversion portions and the metal interconnects.

The solid-state imaging device of the present disclosure includes the light absorbing film between the photoelectric conversion portions and the metal interconnects, and therefore, the incident light from the back surface side can be prevented from being reflected by metal interconnects or the like and thus generating a parasitic light sensitivity.

### BRIEF DESCRIPTION OF THE DRAWINGS

FIG. 1 is a diagram illustrating a pixel circuit for a solid-state imaging device according to a first embodiment of the present disclosure.

FIG. 2 is a diagram illustrating a planar layout pattern corresponding to FIG. 1.

FIG. 3 is a cross-sectional view taken along the line X-X′ in FIG. 2.

FIG. 4 is a view illustrating a step for producing an example solid-state imaging device according to the present disclosure.

FIG. 5 is a view of illustrating a step for producing the example solid-state imaging device subsequent to FIG. 4.

FIG. 6 is a view of illustrating a step for producing the example solid-state imaging device subsequent to FIG. 5.

FIG. 7 is a view of illustrating a step for producing the example solid-state imaging device subsequent to FIG. 6.

FIG. 8 is a view of illustrating a step for producing the example solid-state imaging device subsequent to FIG. 7.

FIG. 9 is a view illustrating a cross-sectional configuration of a solid-state imaging device according to a second embodiment of the present disclosure.

### DETAILED DESCRIPTION

### First Embodiment

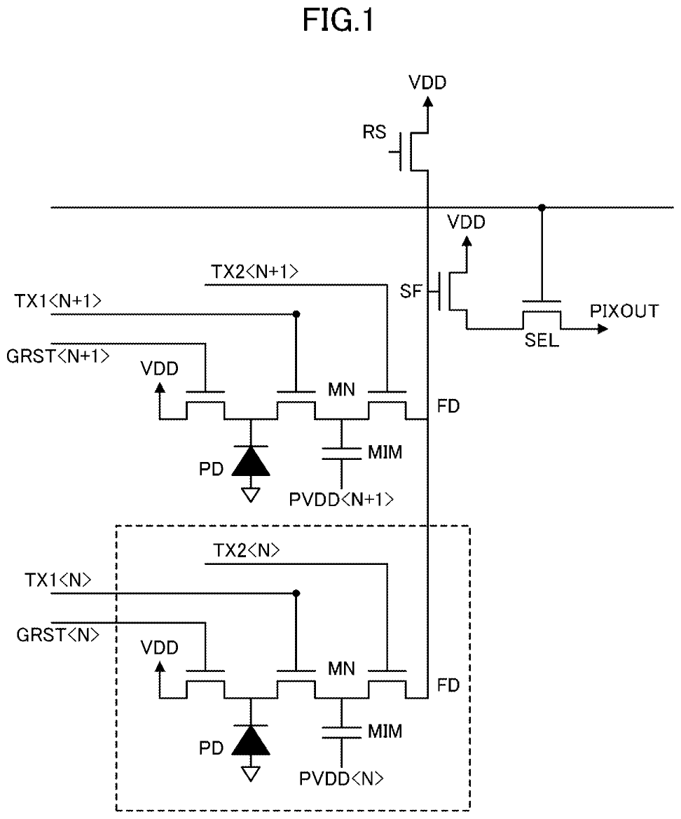

A first embodiment of the present disclosure will be described below with reference to the accompanying drawings. FIG. 1 is a diagram illustrating a pixel circuit of a global shutter system for an example solid-state imaging device according to this embodiment.

In FIG. 1, a pixel system of a two-pixel and one-cell configuration is illustrated, and one of pixels is surrounded by a broken-line rectangle. Each of the pixels includes a photodiode PD that is a photoelectric conversion portion, a transfer transistor TX1 that reads charges from the PD to a memory node MN, a transfer transistor TX2 that reads charges from a memory node portion to a floating diffusion FD, and a global rest transistor GRST that resets charges of the PD. An amplification transistor SF, a reset transistor RS, and a selection transistor SEL are shared by the two pixels.

Each transistor has the following function. First, the GRST transistor is turned on to reses charges of the PD. Thereafter, exposure is started in the PD and charges are generated by photoelectric conversion. Next the RS transistor and the TX2 transistor are turned on to reset charges of the memory node MN, so that the memory node MN is emptied. Next, the TX1 transistor is turned on, and thus, charges generated in the PD are transferred to the memory node MN (charge storage portion) to be stored therein. Because the pixel circuit is of the global shutter system, charges are read simultaneously in all pixels.

The memory node portion is electrically coupled to an MIM capacitor and an upper electrode of the MM capacitor is coupled to a power supply voltage PVDD. After the RS transistor is turned on to reset charges of the FD, charges held in the memory node MN are sequentially read to the FD in accordance with a timing chart of the TX2 transistor. Thus, a potential in the FD is changed and a voltage corresponding to the change of the potential is applied as a gate voltage to the SF transistor. A voltage amplified by the SF transistor is output to a vertical signal line (PIXOUT) in selected one of the pixels by the SEL transistor.

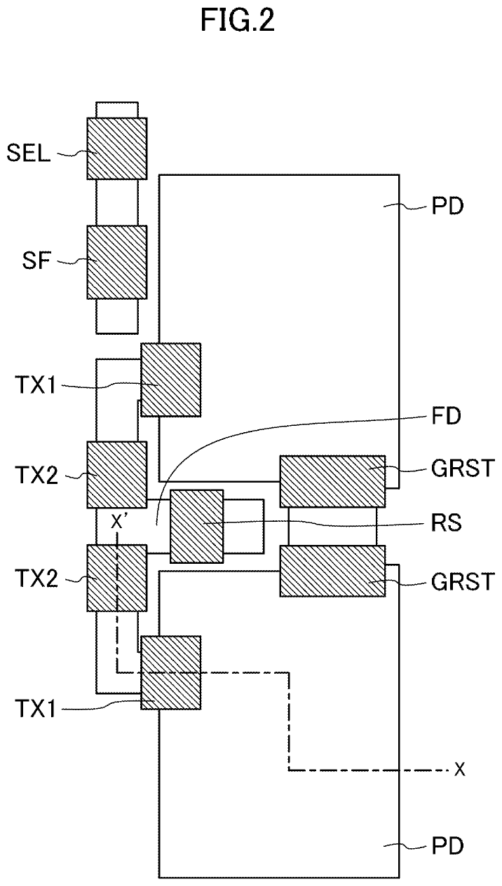

Next, FIG. 2 is a diagram illustrating a planar layout pattern corresponding to the circuit diagram of FIG. 1.

FIG. 2 illustrates a two-pixel one-cell configuration, and two photodiodes PD are disposed so as to be aligned in an up-down direction. As for the TX1 transistor that reads charges from the PD to the memory node MN, the TX2 transistor that reads charges from the MN to the floating diffusion FD, and the GRST transistor that resets the PD, one TX1 transistor, one TX2 transistor, and one GRST transistor are provided for each pixel. On the other hand, as for the amplification transistor SF, the reset transistor RS, and the selection transistor SEL, one amplification transistor SF, one reset transistor RS, and one selection transistor SEL are provided for two pixels.

The MN is disposed between the TX1 transistor and the TX2 transistor and is electrically coupled to the MIM capacitor (not illustrated in FIG. 2). The MN, the SF transistor, the SEL transistor, and the RS transistor are disposed between the pixels.

By reducing an area of the memory node MN and providing the memory node MN between the pixels, an area of PD can be increased.

As for the GRST transistors that reset the PD, each drain portion is coupled to a VDD and the VDD is shared by the two pixels aligned in the up-down direction. By turning on the TX2 transistors, charges held in the memory node MN are transferred to the FD. In this layout, the FD is shared by the two pixels aligned in the up-down direction. The RS transistor is disposed adjacent to the FD.

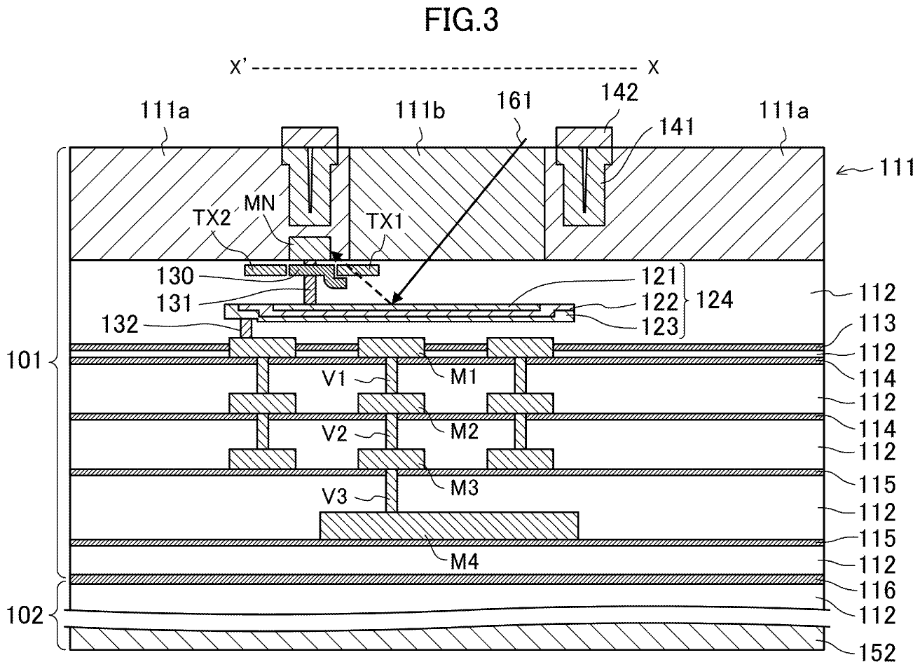

Next, FIG. 3 is a cross-sectional view schematically illustrating a cross section taken along the line X-X′ in FIG. 2. That is, in FIG. 3, a cross section corresponding to the photodiode PD, the TX1 transistor, the memory node MN, and the TX2 transistor is illustrated.

As illustrated in FIG. 3, the solid-state imaging device has a configuration in which a sensor side chip 101 and a logic side chip 102 are bonded to each other and is a back-side irradiation type image sensor.

The sensor side chip 101 includes a first semiconductor substrate 111 and an interconnect layer, and mainly constituent components, such as a photodiode, a memory node, or the like, related to pixel characteristics are formed therein. The logic side chip 102 includes a second semiconductor substrate 152 and an interconnect layer, and mainly transistors, such as a signal processing circuit, a driving circuit, a control circuit, or the like, and the interconnect layer are formed therein.

The interconnect layer of the sensor side chip 101 has a configuration in which tetra ethoxy silane (TEOS) films 112 that are insulation films are stacked and metal interconnects M1, M2, M3, and M4 of a plurality of layers (four layers in an example of FIG. 3) and via plugs V1, V2, and V3 that connect these layers with each other are formed in the TEOS films 112. As insulation films, an Si-CN film 113, a P—SiN film 114, an SiCN/SiCO film 115, and the like are also used.

In the first semiconductor substrate 111, a photo diode 111b and the memory node MN are formed. In the TEOS film 112 directly below the first semiconductor substrate 111, the TX1 transistor that reads charges from the photo diode 111b to the memory node MN and the TX2 transistor that reads charges from the memory node MN are formed. Note that, as for the TX1 transistor and the TX2 transistor, positions in which the TX1 transistor and the TX2 transistor are formed are illustrated and specific configurations of respective sources and drains or the like are not illustrated. A polysilicon layer 130 provided in the TEOS film 112 is electrically coupled to the memory node MN.

Furthermore, a metal-insulator-metal (MIM) capacitor 124 is formed in the TEOS film 112 directly below the first semiconductor substrate 111. The MIM capacitor 124 includes electrodes each of which is made of a material having a light-absorbing property. For example, a lower electrode 121 and an upper electrode 123 are TiN electrodes. An insulation film 122 made of a high dielectric material, that is, for example, HfO₂ or the like, is provided between the lower electrode 121 and the upper electrode 123 to thus form an MIM structure.

The MIM capacitor 124 absorbs light 161 that has entered the photo diode 111b from a back surface side, so that reflection of the light 161 by the metal interconnect M1 or the like and entrance of the light 161 to the memory node MN, the TX1 transistor (specifically, a drain), or the like are suppressed. That is, in FIG. 3, if the lower electrode 121 reflects light, there is a probability that the light 161 enters the memory node MN as in a portion indicated by a broken line, and this causes a parasitic light sensitivity. However, the lower electrode 121 is formed of TiN or the like that absorbs light, and therefore, such reflection does not occur, so that light in the portion indicated by the broken line is not generated and a parasitic light sensitivity can be suppressed. Note that at least one of the lower electrode 121 and the upper electrode 123 may function as a light-absorbing film.

For this purpose, the MIM capacitor 124 (specifically, the lower electrode 121) is provided in a region (region overlapping with the photo diode 111b when viewed perpendicularly to a back surface of the first semiconductor substrate 111) covering the photo diode 111b.

The lower electrode 121 is coupled to the memory node MN via a via plug 131 and the polysilicon layer 130. The upper electrode 123 is coupled to the metal interconnect M1 connected to the PVDD and a capacitance of the MIM capacitor 124 can be adjusted by applying a voltage of the PVDD. The upper electrode 123 is coupled to the metal interconnect M1 via a contact plug 132.

Herein, the MIM capacitor 124 is preferably disposed in the interconnect layer of the sensor side chip 101. This is for the purpose of facilitating production, in addition to reducing the parasitic light sensitivity as described above.

That is, the MIM capacitor 124 is provided for the photo diode 111b in each pixel, and therefore, if the MIM capacitor 124 is disposed in the logic side chip 102, Cu—Cu bonding for each pixel pitch is needed in each of the sensor side chip 101 and the logic side chip 102. This requires positioning with very high accuracy, so that processing is difficult. Specifically, it is expected that, as the pixel pitch is further reduced and a pixel property is further increased, a yield is further reduced,

On the other hand, as illustrated in FIG. 3, when the MIM capacitor 124 is provided in the sensor side chip 101, Cu—Cu bonding for each pixel pitch is not needed. Therefore, accuracy required in bonding chips to each other can be lowered. As a result, it can be made it easier to cope with miniaturization of and increase in pixel property of the solid-state imaging device.

Next, the memory node MN will be described. The memory node MN is provided in a deeper side (an interconnect layer side or an opposite side to a back surface that light enters) in the first semiconductor substrate 111. In the solid-state imaging device of this disclosure, as a result of increasing an area of each photo diode 111b, a width of the isolation region between the photo diodes 111b has been reduced. The memory node MN is disposed in the isolation region with this reduced width. In order to realize this, the area of the memory node MN is reduced and the memory node MN is disposed below the isolation region. When the area of the memory node MN is reduced, incident light is less likely to enter the memory node MN, and therefore, parasitic light sensitivity characteristics are improved. Specifically, a width of the memory node MN is preferably smaller than the width of the isolation region.

When the area of the memory node MN is reduced, a capacitance for storing charges of the memory node MN is reduced in size. Therefore, the memory node MN is electrically coupled to the MIM capacitor 124 to ensure a necessary capacitance.

Note that, as the MIM capacitor provided to ensure a necessary capacitance in the memory node MN, a high dielectric material is formed so as to be interposed between metal interconnects. However, in such a case, an interconnect in a portion in which a capacitance is desired to be kept small is affected in some cases. For example, in the configuration of Japanese Patent No. 4835710, there is a probability that the capacitance of the interconnect is extremely high and a read failure of the transfer transistor occurs.

On the other hand, as illustrated in FIG. 3, the MIM capacitor 124 is formed separately from the metal interconnects, and thus, influence on the interconnect capacitance can be reduced.

As for the photo diode 111b, saturation characteristics can be improved by increasing the area thereof.

Next, a deep trench isolation (DTI) 141 and a metal grid 142 will be described.

The DTI 141 is an isolation layer formed by forming a trench in the first semiconductor substrate 111 from the back surface side and burying an insulative material therein, and is disposed between pixels. Herein, a material having a light shielding property, that is, for example, tungsten, is used as the material buried in the trench, the DTI 141 also functions as a light shielding film. In the solid-state imaging device of FIG. 3, the DTI 141 is disposed around the 111b and isolates the photo diode 111b from an adjacent photodiode (not illustrated). The DTI 141 suppresses color mixing between pixels. Furthermore, by disposing the memory node MN between pixels and then disposing the DTI 141 thereabove (in the back surface side), the DTI 141 can perform a function of shielding the memory node MN from light.

The metal grid 142 is a patterned metal layer formed on the first semiconductor substrate 111, functions as a light shielding film, and is used for preventing color mixing between pixels or the like. Particularly for incident light with a large angle, the metal grid 142 is useful because the metal grid 142 can prevent light from entering the adjacent photo diode 111b.

If the metal grid 142 is disposed on the DTI 141 and also is formed of the same material (tungsten or the like) as the material buried in the DTI 141, the DTI 141 and the metal grid 142 can be integrally formed, so that the number of production steps can be reduced and the DTI 141 and the metal grid 142 can be stably formed.

The logic side chip 102 is formed using the second semiconductor substrate 152. Although a detailed configuration thereof will not be described, a TEOS film 112 is provided in an uppermost layer on the second semiconductor substrate 152 and is bonded to one of the TEOS films 112 of the sensor side chip 101 via an SiCN film 116.

### <Method for Producing Solid-State Imaging Device>

Next, a method for producing a solid-state imaging device according to the present disclosure will be described. The solid-state imaging device is a back-side irradiation type image sensor, and therefore, is produced by a method in which the sensor side chip 101 and the logic side chip 102 are bonded to each other.

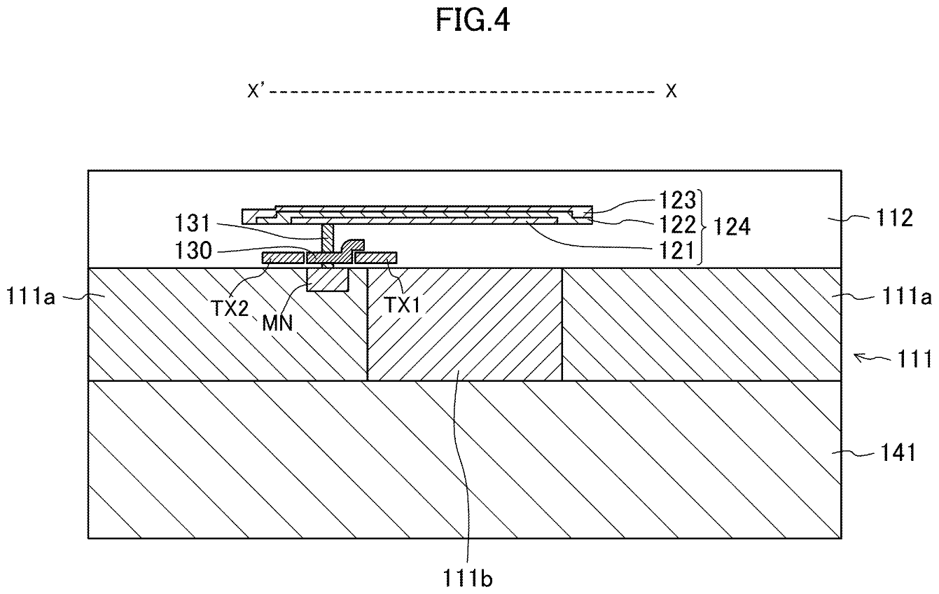

FIG. 4 is a view illustrating a step for producing the sensor side chip 101. In FIG. 4, the cross section illustrated in FIG. 3 is turned upside down (furthermore, illustrates the cross section from an opposite side of the line X-X′).

A p-type substrate 151 is prepared and an n-type epitaxial layer is formed thereon. The epitaxial layer serves as the first semiconductor substrate 111 in FIG. 3. In the first semiconductor substrate 111, p-type ions are injected to a vicinity of a substrate surface and n-type ions are injected to a portion deeper in the substrate than the vicinity of the substrate surface, thereby forming the photo diode 111b. The other portion of the first semiconductor substrate 111 than the photo diode 111b remains as an n-type layer 111a.

Next, in order to form the memory node MN, n-type ions are injected to a vicinity of a surface of the n-type layer 111a. Thereafter, a gate electrode of a transistor (TX1, TX2, or the like) of each pixel is formed.

For coupling of the MIM capacitor 124 and the memory node MN, damage on the substrate is preferably suppressed. Therefore, the polysilicon layer 130 is formed and the coupling is performed via the polysilicon layer 130.

Subsequently, an interlayer isolation film (the TEOS film 112, and in FIG. 4, a thickness up to a lower surface of the lower electrode 121) is formed. Furthermore, the via plug 131 that couples to the polysilicon layer 130 is formed. For example, a hole is formed by etching and a conductive material is buried therein, thereby forming the via plug 131.

Subsequently, the lower electrode 121 is formed. To form the lower electrode 121, a TiN film is deposited on a portion of the TEOS film 112 in which the lower electrode 121 is to be formed, and then, etching is performed using a mask having a pattern of the lower electrode 121. Thus, the lower electrode 121 coupled to the polysilicon layer 130 via the via plug 131 is formed.

Next, an HfO₂ film that is a high dielectric material is deposited, and furthermore, a TiN film used for forming the upper electrode 123 is deposited thereon. Thereafter, using a mask having a pattern of the upper electrode 123, the TiN film and the HfO₂ film are etched. Thus, the MIM capacitor 124 in which the insulation film 122 is interposed between the lower electrode 121 and the upper electrode 123 is formed.

Thereafter, the rest of the TEOS film 112 in FIG. 4 and other interconnects or the like (not illustrated) therein will be formed in order.

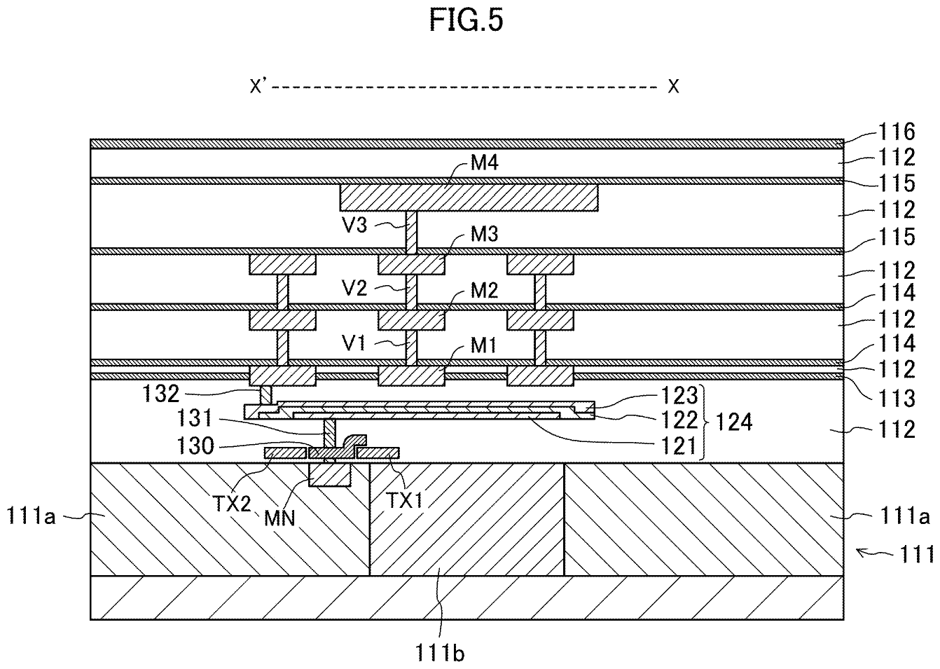

Next, a step in FIG. 5 will be described. In this step, an interconnect layer is formed on the TEOS film 112 including the MIM capacitor 124.

First, a contact hole used for coupling the upper electrode 123 is formed in the TEOS film 112 including the MIM capacitor 124 and the contact plug 132 is formed by depositing a metal thin film. Thereafter, an insulation layer including the metal interconnects M1, M2, M3, and M4 and the via plugs V1, V2, and V3 is formed. The insulation layer mainly includes the TEOS films 112 and has a configuration in which the Si—CN film 113, the P—SiN film 114, the SiCN/SiCO film 115 are interposed between the plurality of TEOS films 112.

A normal interconnect formation flow, such as a damascene process or the like, may be used for forming the metal interconnects M1 to M4 and the via plugs V1 to V3. That is, an interconnect trench pattern is formed in the insulation layer (mainly the TEOS films 112) by etching or the like, and thereafter, a metal thin film is formed on an entire surface so as to fill the interconnect trench pattern. Furthermore, a surface of the metal thin film is planarized by chemical mechanical polishing (CMP) or the like, thereby forming the metal interconnects M1 to M4 and the via plugs V1 to V3 in the interconnect trench pattern.

Note that after the metal interconnects M1 and M2 are formed, the P—SiN film 114 is formed before the TEOS film 112 of a next layer is formed. Similarly, after the metal interconnects M3 and M4 are formed, the SiCN/SiCO film 115 is formed before the TEOS film 112 of a next layer is formed.

After the SiCN/SiCO film 115 on the metal interconnect M4 is formed, the TEOS film 112 and the SiCN film 116 are further formed.

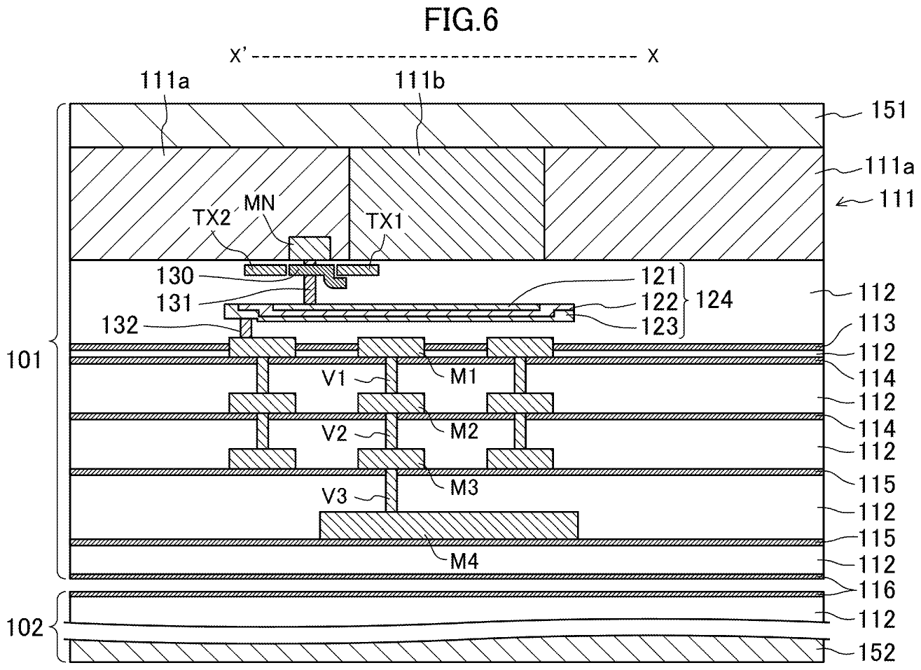

Next, as illustrated in FIG. 6, the sensor side chip 101 of FIG. 5 is bonded to the logic side chip 102. Note that, in FIG. 6, the sensor side chip 101 illustrated in FIG. 5 is illustrated upside down again. Bonding is performed such that the respective SiCN films 116 provided on the respective TEOS films 112 are put together. For example, respective surfaces of the both chips to be bonded are activated by plasma processing or the like and are brought into contact with each other. Thus, a Van der Waals force (intermolecular force) acts on the surfaces, so that the surfaces are bonded to each other. Furthermore, anneal processing is performed to form a covalent bond on a bonded surface, so that a firm bonding can be achieved.

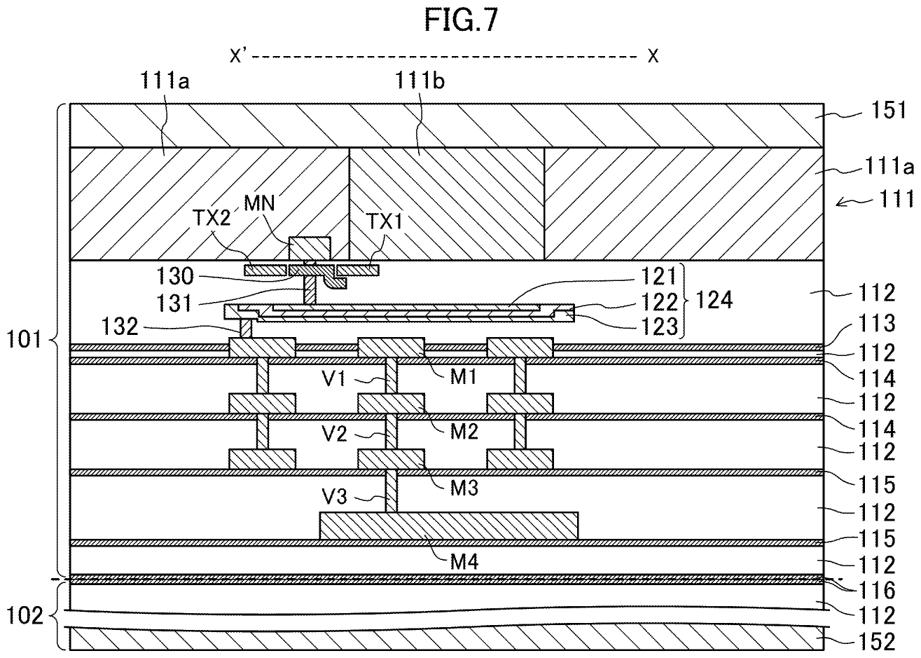

In FIG. 7, a state after such bonding has been performed is illustrated. The sensor side chip 101 and the logic side chip 102 are not only physically bonded to each other but also electrically coupled to each other using a through-silicon via (TSV) electrode (TSV is not illustrated). A method (Cu—Cu bonding) in which a Cu pad or the like is exposed at a bonding interface of each of the both chips and the pads are bonded to each other to thus ensure electrical conduction may be used.

After the chips are bonded to each other, the substrate 151 is polished and removed, so that the photo diode 111b is exposed.

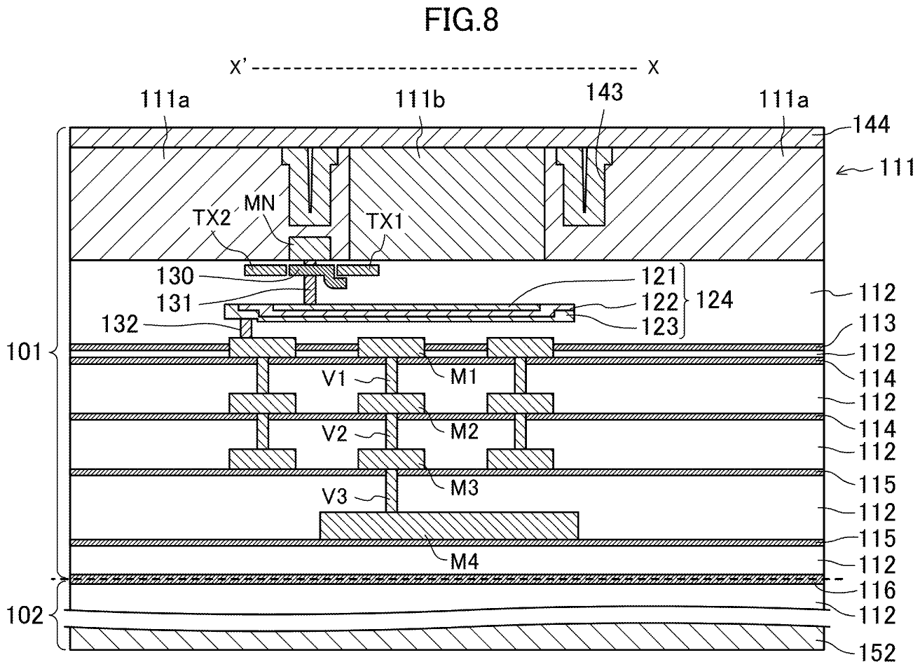

Next, a step of FIG. 8 will be described. In this step, for the purpose of light shielding for the memory node MN and reduction of crosstalk, the DTI 141 is formed. In order to form the DTI 141, the first semiconductor substrate 111 (the n-type layer 111a) is etched up to a vicinity of the memory node MN, thereby forming a deep trench 143. Next, a seed layer (not illustrated) of TiN or the like is deposited to cover side surfaces and a bottom surface of the trench 143, and then, a tungsten film 144 is formed in the trench 143 and on the first semiconductor substrate 111. Furthermore, the tungsten film 144 is planarized by a CMP method. This state is illustrated in FIG. 8.

As for a depth of the trench 143, in view of a light shielding property, it is preferable that the trench 143 is provided so as to extend to a position directly above the memory node MN and the n-type layer 111a is not left remaining between the DTI 141 and the memory node MN. However, the memory node MN is possibly damaged by etching performed in forming the trench 143 or the like. Therefore, in order to avoid the damage, the n-type layer 111a is left remaining between the memory node MN and the trench 143. If the above-described damage is avoided or restored, the n-type layer 111a is not needed to be left remaining.

Thereafter, the tungsten film 144 is etched to be patterned such that a portion thereof on the photo diode 111b is opened, thereby forming the metal grid 142 (see FIG. 3).

If an oxide film is used as a filling material of the trench 143 used for forming the DTI 141, the DTI 141 needs to be formed in a separate step from a step forming the metal grid 142. However, by employing the above-described step in which tungsten is also used as the filling material, tungsten films used for filling the trench 143 and forming the metal grid 142 can be formed in the same step. Therefore, the number of steps can be reduced and production cost is reduced.

### Second Embodiment

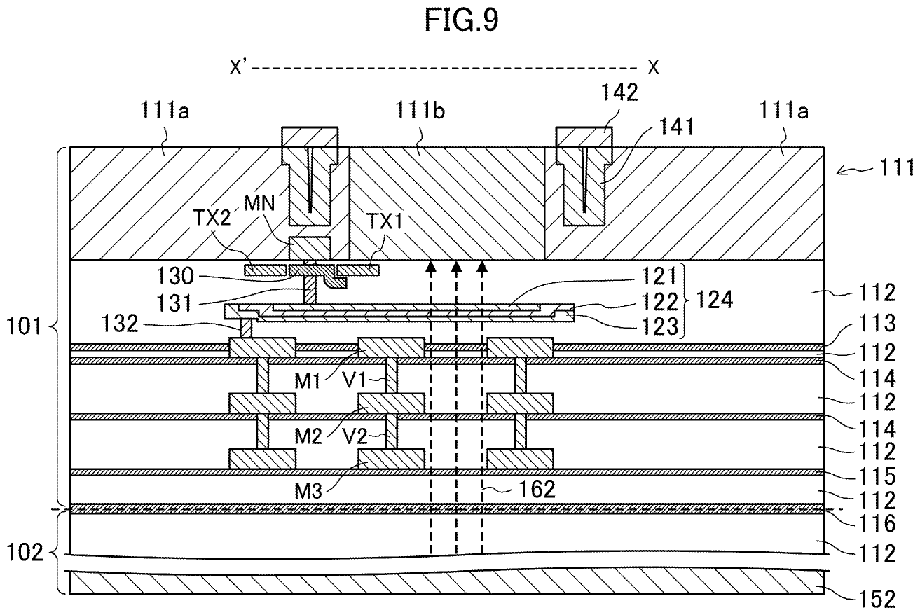

Next, with reference to FIG. 9, a solid-state imaging device according to a second embodiment of the present disclosure will be described. Many components are common with the solid-state imaging device of the first embodiment illustrated in FIG. 3, and therefore, each constituent component equivalent to a corresponding component in the first embodiment will be denoted by the same reference character as that of the corresponding component, and different points will be mainly described. A pixel circuit and a planar layout pattern are similar to those in FIG. 1 and FIG. 2.

The solid-state imaging device of FIG. 3 includes the metal interconnects M1, M2, M3, and M4 of four layers and the via plugs V1, V2, and V3 of three layers that couple the metal interconnects to each other. On the other hand, in the solid-state imaging device of FIG. 9, an interconnect layer has a three-layer configuration, and the metal interconnect M4 of a fourth layer of the interconnects and the via plug V3 of a third layer of the via plugs couped thereto are not formed. Accordingly, the TEOS film 112 including the metal interconnect M4 in FIG. 3 is not formed.

In a structure in which a sensor side chip 101 and a logic side chip 102 are bonded to each other, electromagnetic waves are generated in a circuit of the logic side chip 102 and the electromagnetic waves enter the sensor side chip 101 to be noise, so that pixel characteristics are deteriorated in some cases. Therefore, an interconnect that blocks the electromagnetic waves is disposed in at least one of the sensor side chip 101 and the logic side chip 102, and also, a photodiode portion is blocked.

In the solid-state imaging device of FIG. 3, for the above-described purpose, the metal interconnect M4 of the fourth layer is disposed as a shield layer. However, the layout in which the MIM capacitor 124 is disposed between the interconnect layer and the photo diode 111b and covers the photo diode 111b is employed. Accordingly, the MIM capacitor 124 performs a function of blocking the electromagnetic waves from the logic side chip 102. That is, even when the metal interconnect M4 of the fourth layer is not provided, degradation of image quality due to the electromagnetic waves from the logic side chip 102 can be suppressed.

In FIG. 9, electromagnetic waves 162 from the logic side chip 102 are indicated by arrows of broken lines. The electromagnetic waves 162 are blocked by the MIM capacitor 124 even without the metal interconnect M4 of the fourth layer, and entrance of the electromagnetic waves 162 to the photo diode 111b is suppressed.

As described above, according to the solid-state imaging device of the second embodiment, the metal interconnect M4 of the fourth layer and a layer of an insulation film including the metal interconnect M4 or the like can be omitted, so that materials and production steps can be reduced and cost can be reduced.

According to a technology disclosed herein, PLS characteristics can be improved in a back-side irradiation type solid-state imaging device and a solid-state imaging device according to the present disclosure is useful as a solid-state imaging device used for various types of cameras.

What is claimed is:

1. A solid-state imaging device, comprising:
a first semiconductor substrate;
photoelectric conversion portions arrayed on the first semiconductor substrate and configured to convert incident light to charges;
a charge storage portion configured to hold charges transferred from a corresponding one of the photoelectric conversion portions via a transfer transistor; and
an interconnect layer stacked on the first semiconductor substrate and including a plurality of metal interconnects,
wherein
the incident light enters the first semiconductor substrate from a back surface side that is an opposite side to the interconnect layer, and
the solid-state imaging device further includes a light absorbing film between the photoelectric conversion portions and the metal interconnects.

2. The solid-state imaging device of claim 1, wherein
the light absorbing film is formed using titanium nitride.

3. The solid-state imaging device of claim 2, further comprising:
an MIM capacitor configured such that an insulation film formed of a high dielectric material is interposed between an upper electrode and a lower electrode,
wherein
at least one of the upper electrode and the lower electrode is formed using the light absorbing film.

4. The solid-state imaging device of claim 3, wherein
the MIM capacitor is located below a corresponding one of the photoelectric conversion portions and in a region overlapping the photoelectric conversion portion when viewed perpendicularly to a back surface of the first semiconductor substrate.

5. The solid-state imaging device of claim 4, wherein
the MIM capacitor is coupled to the charge storage portion.

6. The solid-state imaging device of claim 1, further comprising:
a second semiconductor substrate bonded to the first semiconductor substrate via the interconnect layer,
wherein
the light absorbing film is provided in the first semiconductor substrate.

7. The solid-state imaging device of claim 1, further comprising:
an inter-pixel insulation region provided between the photoelectric conversion portions,
wherein
the charge storage portion is located below the inter-pixel isolation region, and
a width of the charge storage portion is equal to or smaller than a width of the inter-pixel isolation region.

8. The solid-state imaging device of claim 7, wherein
the inter-pixel isolation region includes an isolation region that prevents color mixing of adjacent ones of the photoelectric conversion portions.

9. The solid-state imaging device of claim 8, wherein
the isolation region has a configuration in which a light shielding material is buried in a trench provided in the first semiconductor substrate and is disposed above the charge storage portion.

10. The solid-state imaging device of claim 8, further comprising:
a light shielding layer provided on the isolation region.

11. The solid-state imaging device of claim 10, wherein
the isolation region and the light shielding layer are integrally formed.
